(19) United States
(12) Patent Application Publication
(10) Pub. No.: US 2016/0315199 A1
(43) Pub. Date: Oct. 27, 2016

(54) PHOTO MASK, THIN FILM TRANSISTOR AND METHOD FOR MANUFACTURING THIN FILM TRANSISTOR

(71) Applicant: SHENZHEN CHINA STAR OPTOELECTRONICS TECHNOLOGY CO., LTD, Shenzhen, Guangdong (CN)

(72) Inventor: Zhiguang YI, Shenzhen, Guangdong (CN)

(21) Appl. No.: 14/777,130

(22) PCT Filed: Jan. 24, 2014
(86) PCT No.: PCT/CN2014/071426

§ 371 Date: Oct. 1, 2015

(30) Foreign Application Priority Data
Dec. 26, 2013 (CN) 201310733217.9

(51) Int. Cl. H01L 29/786; G03F 7/20; H01L 29/66; H01L 21/027; H01L 21/3213; H01L 27/12; G03F 1/32; G03F 7/32

(52) U.S. Cl. CPC H01L 29/78669; G03F 1/32; G03F 7/20; G03F 7/32; H01L 21/0274; H01L 21/32139; H01L 27/1288; H01L 29/66765

(57) ABSTRACT

The present invention discloses a photo mask for defining the pattern of a data layer and a semiconductor layer of a thin film transistor. The photo mask has a number of slits passing through the photo mask. The slits are parallel to each other and are arranged at an equal distance. An opaque pattern area, which precludes the slits in the photo mask, is defined. The opaque patter area surrounds the slits.

### FIELD OF THE INVENTION

The present invention relates to liquid crystal display technologies, and particularly, to a thin film transistor, a photo mask for defining the thin film transistor, and a method for manufacturing the thin film transistor.

### BACKGROUND OF THE INVENTION

In the thin film transistor liquid crystal display (TFT-LCD), a thin film transistor servers as a switch component controlling each pixel electrode.

When manufacturing the thin film transistor using a photo mask, the thickness of a semiconductor layer remain is needed to be measured at a channel of the thin film transistor to monitor the manufacturing process. Currently, the photo mask is a single slit mask. The semiconductor layer can be exposure only if applying wet-etching twice and dry-etching once on the substrate at the single slit. Another dry-etching is then applied to the substrate to form the channel in the semiconductor layer. The channel is short as the single slit is short. This may affect the measurement accuracy of the thickness of the semiconductor layer remain. Thus, quality of the thin film transistor is difficult to be effectively controlled.

Therefore, it is desired to provide a thin film transistor, a photo mask for defining the thin film transistor, and a method for manufacturing the thin film transistor, which can overcome or at least alleviate the above-mentioned problem.

### SUMMARY OF THE INVENTION

To solve the above-mentioned problem, the present invention provides a photo mask for defining the pattern of a data layer and a semiconductor layer of a thin film transistor. The photo mask has a number of slits passing through the photo mask. The slits are parallel to each other and are arranged at an equal distance. An opaque pattern area, which precludes the slits in the photo mask, is defined. The opaque patter area surrounds the slits.

Wherein, each slit is substantially an elongated rectangle.

Wherein, the width of each slit is in a range from 1.5 micrometers to 2.5 micrometers.

Wherein, the opaque patter area is made of opaque material having transmittance of 0%.

To solve the above-mentioned problem, the present invention provides a thin film transistor formed by the said photo mask. The thin film transistor comprises a substrate, a gate electrode formed on the substrate, a gate insulating layer formed on and covering the gate electrode, a semiconductor layer formed on the gate insulating layer, a doped semiconductor layer, and a data layer. The semiconductor layer comprises a flat portion and a plurality of protruding portions protruding from the flat portion. The protruding portions are arranged at an equal distance and are parallel to each other. The flat portion corresponds to the opaque pattern area. The protruding portions correspond to the slits. The doped semiconductor layer is formed on the protruding portions. The data layer has a plurality of data strips. The data strips are arranged at an equal distance and are parallel to each other. Each data strip is formed on the doped semiconductor layer and corresponds to the protruding portion. The pattern of the data layer is defined by the photo mask.

Wherein, the substrate is made of glass or plastic.

Wherein, the gate electrode is a Mo layer, an aluminum layer, a titanium layer, a copper layer, or two layers stacked one on another selected from the Mo layer, the aluminum layer, the titanium layer, and the copper layer.

Wherein, the gate insulating layer is a SiNx layer.

Wherein, the semiconductor layer is an amorphous silicon (a-Si) semiconductor layer.

Wherein, each protruding portion and each data strip are substantially elongated rectangles.

Wherein, the width of each protruding portion is in a range from 1.5 micrometers to 2.5 micrometers, and the width of each data strip is in a range from 1.5 micrometers to 2.5 micrometers.

To solve the above-mentioned problem, the present invention provides a method for manufacturing a thin film transistor using the photo mask. The method includes: providing a substrate and forming a gate electrode, a gate insulating layer, a semiconductor layer, a doped semiconductor layer, and a data layer on the substrate in an order which is far away from the substrate; forming an initial photoresist layer on the data layer; forming an intermediate photoresist layer by means of removing the initial photoresist layer of a certain thickness using a wet-etching process; providing a photo mask, the photo mask having a plurality of slits passing through the photo mask, the slits being parallel to each other and arranged at an equal distance, an opaque pattern area which precluding the slits in the photo mask being defined, the opaque patter area surrounding the slits; forming a photoresist layer remain by means of removing portions of the intermediate photoresist layer corresponding to the opaque pattern area using a dry-etching process; removing portions of the data layer uncovered by the photoresist layer remain via a dry-etching process; removing portions of the doped semiconductor layer uncovered by the photoresist layer remain and portions of the semiconductor layer uncovered by the photoresist layer remain via a dry-etching process; and removing the photoresist layer remain.

Wherein, the step of forming the photoresist layer remain comprises: exposing the intermediate photoresist layer by means of striking light on the intermediate photoresist layer though the photo mask; and developing the intermediate photoresist layer, thereby retaining portions of the intermediate photoresist layer which are stroked by light, and removing portions of the intermediate photoresist layer which are not stroked by light.

Wherein, each slit is substantially an elongated rectangle.

Wherein, the width of each slit is in a range from 1.5 micrometers to 2.5 micrometers.

Wherein, the opaque patter area is made of opaque material having transmittance of 0%.

Wherein, the substrate is made of glass or plastic.

Wherein, the gate electrode is a Mo layer, an aluminum layer, a titanium layer, a copper layer, or two layers stacked one on another selected from the Mo layer, the aluminum layer, the titanium layer, and the copper layer.

Wherein, the gate insulating layer is a SiNx layer.

Wherein, the semiconductor layer is an amorphous silicon (a-Si) semiconductor layer.

In the thin film transistor and the method for manufacturing the thin film transistor using the photo mask, the semiconductor layer is exposed. Thus, the thickness of the semiconductor layer can be easily measured as measuring the thickness of the semiconductor layer is not limited by the channel. This can insure the measurement accuracy of the thickness of the semiconductor layer. Thus, quality of the thin film transistor is easily controlled.

### BRIEF DESCRIPTION OF THE DRAWINGS

In order to illustrate technical schemes of the present invention or the prior art more clearly, the following section briefly introduces drawings used to describe the embodiments and prior art. Obviously, the drawing in the following descriptions just is some embodiments of the present invention. The ordinary person in the related art can acquire the other drawings according to these drawings without offering creative effort.

FIG. 1 is a cross-sectional view of a photo mask in accordance with a first exemplary embodiment of the present invention;

FIGS. 2-7 are schematic views showing a method for manufacturing a thin film transistor using the photo mask of FIG. 1, in accordance with a second exemplary embodiment of the present invention; and

FIG. 8 is a top view of the thin film transistor of FIG. 7.

### DETAILED DESCRIPTION OF THE PREFERRED EMBODIMENTS

The following sections offer a clear, complete description of the present invention in combination with the embodiments and accompanying drawings. Obviously, the embodiments described herein are only a part of, but not all of the embodiments of the present invention. In view of the embodiments described herein, any other embodiment obtained by the person skilled in the field without offering creative effort is included in a scope claimed by the present invention.

### The First Embodiment

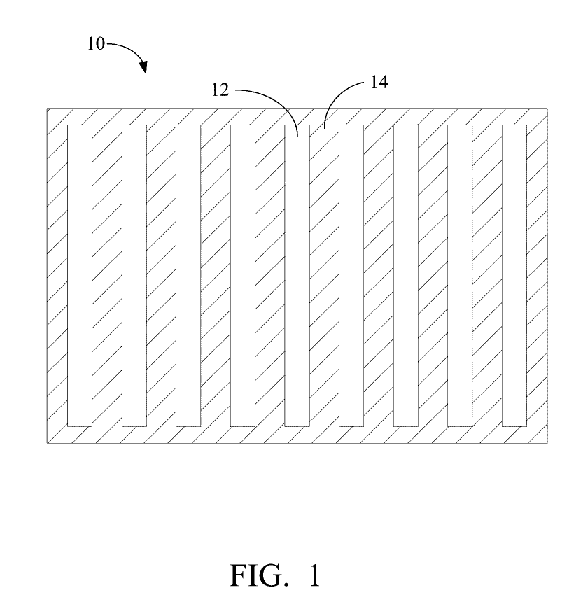

Referring to FIG. 1, a photo mask 10, in accordance with a first embodiment, is substantially rectangular and can be a graytone mask (GTM), a halftone mask (HTM), or other masks having different transmittance at different regions. In this embodiment, the photo mask 10 defines a number of slits 12. The slits 12 are substantially parallel to each other and are spaced apart from each other. The slits 12 are arranged in a matrix. Each slit 12 is substantially an elongated rectangle, and the width of each slit 12 is in a range from 1.5 micrometers to 2.5 micrometers. An opaque pattern area 14, which precludes the slits 12 in the photo mask 10, is defined. The opaque patter area 14 surrounds the slits 12, and is made of opaque material having transmittance of 0%.

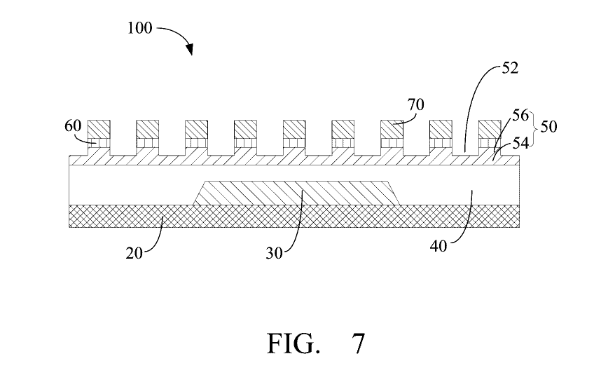

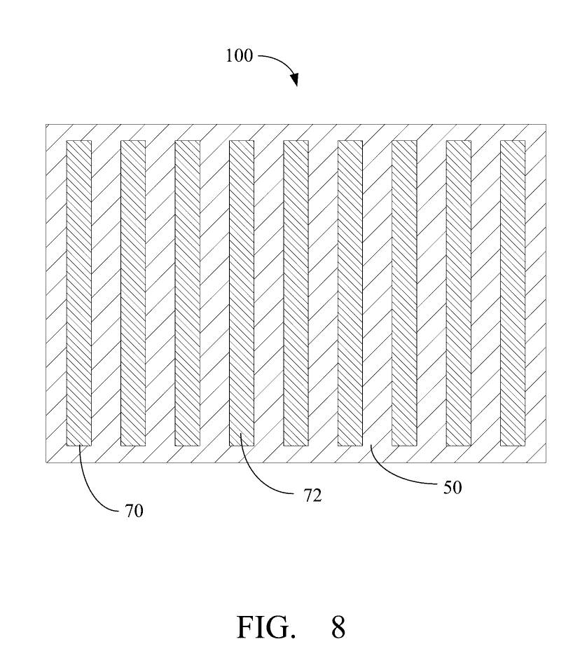

Referring to FIGS. 7-8, the photo mask 10 of this embodiment is configured to define the pattern of a data layer 70 and a semiconductor layer 50 of a thin film transistor 100. In detail, the slits 12 are configured to define the patter of the data layer 70, and the opaque pattern area 14 is configured to define the width of each channel 52.

### The Second Embodiment

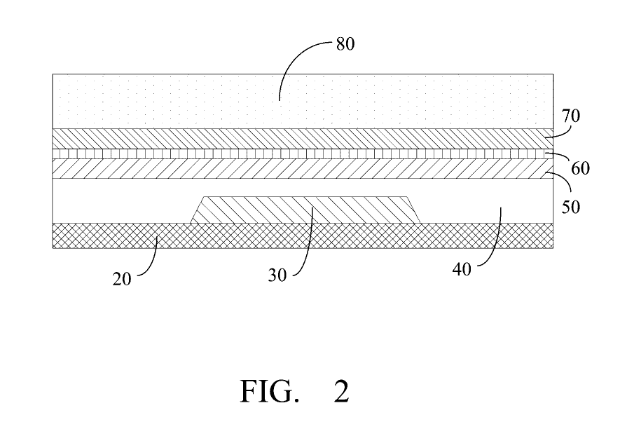

Referring to FIGS. 2-7, a method for manufacturing the thin film transistor 100 (show in FIG. 8) using the photo mask 10 of the first embodiment, in accordance with a second embodiment, includes the following steps.

First, referring to FIG. 2, a substrate 20 is provided, and a gate electrode 30, a gate insulating layer 40, a semiconductor layer 50, a doped semiconductor layer (or ohmic contact layer) 60, and a data layer 70 are formed on the substrate 20 in an order which is far away from the substrate 20. The substrate 20 can be made of glass or plastic. In this embodiment, the substrate 20 is made of glass. The gate electrode 30 can be a Mo layer, an aluminum layer, a titanium layer, a copper layer, or two layers stacked one on another selected from the said layers. The gate insulating layer 40 is a SiNx layer. The semiconductor layer 50 is an amorphous silicon (a-Si) semiconductor layer.

Second, referring to FIG. 2, an initial photoresist layer 80 is formed on the data layer 70. D represents that a thickness of the initial photoresist layer 80. In this embodiment, the initial photoresist layer 80 is a negative photoresist layer. After an exposure process and a development process, portions of the initial photoresist layer 80, which are stroked by light, can be retained. Portions of the initial photoresist layer 80, which are not stroked by light, are removed.

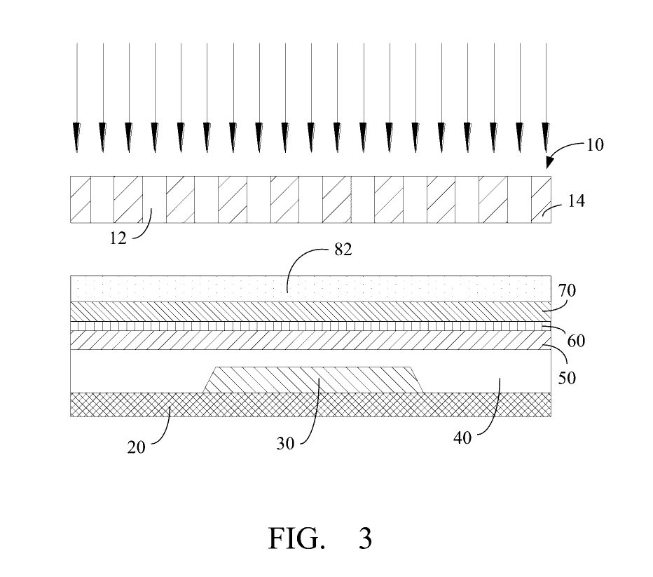

Third, referring to FIG. 3, the initial photoresist layer 80 with a certain thickness is removed using a wet-etching process, thereby forming an intermediate photoresist layer 82 with a thickness less than D.

Fourth, referring to FIG. 3, a photo mask 10 is provided. The structure of the photo mask 10 is the same as that of the photo mask 10 of the first embodiment.

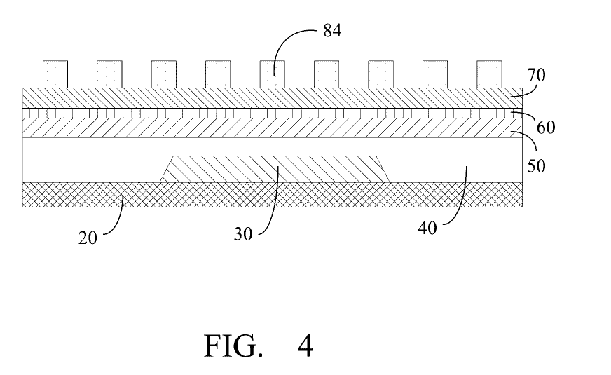

Fifth, referring to FIGS. 3-4, portions of the intermediate photoresist layer 82 corresponding to the opaque pattern area 14 is removed using a dry-etching process. In detail, the intermediate photoresist layer 82 is first exposed by means of striking light on the intermediate photoresist layer 82 though the photo mask 10. Then, the intermediate photoresist layer 82 is developed, thus portions of the intermediate photoresist layer 82 which are stroked by light are retained, and portions of the intermediate photoresist layer 82 which are not stroked by light are removed. That is, after the development process, portions of the intermediate photoresist layer 82 corresponding to the slits 12 are kept, and portions of the intermediate photoresist layer 82 corresponding to the opaque pattern area 14 are removed. Thus, a photoresist layer remain 84 is formed.

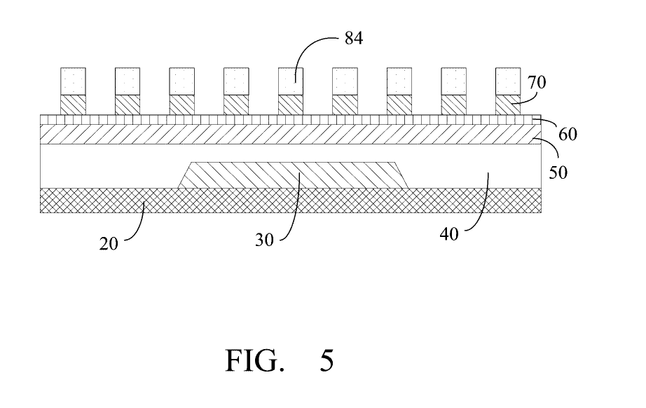

Sixth, referring to FIGS. 4-5, portions of the data layer 70 uncovered by the photoresist layer remain 84 are removed using a dry-etching process.

s

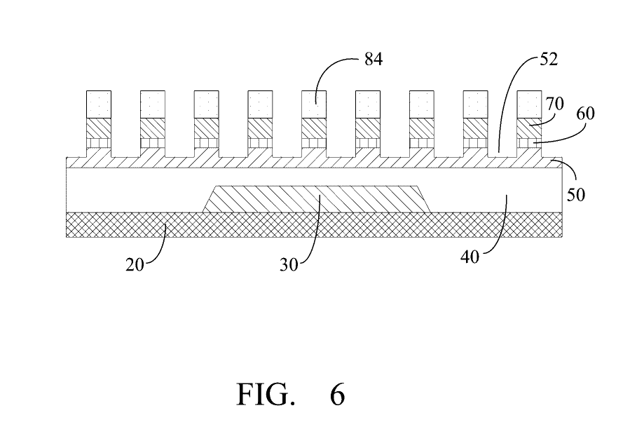

Seventh, referring to FIGS. 5-6, portions of the doped semiconductor layer 60 uncovered by the photoresist layer remain 84 and portions of the semiconductor layer 50 uncovered by the photoresist layer remain 84 are removed using a dry-etching process. Thus, a number of channels 52 are formed, and the semiconductor layer 50 is exposed at the channels 52.

Eighth, the photoresist layer remain 84 is removed to form a thin film transistor 100.

### The Third Embodiment

Referring to FIGS. 7-8, a thin film transistor 100, in accordance with a third embodiment, includes a substrate 20, a gate electrode 30, a gate insulating layer 40, a semiconductor layer 50, a doped semiconductor layer 60, and a data layer 70.

The substrate 20 is made of glass or plastic. In this embodiment, the substrate 20 is made of glass. The gate electrode 30 is formed on the substrate 20, and can be a Mo layer, an aluminum layer, a titanium layer, a copper layer, or two layers stacked one on another selected from the said layers. The gate insulating layer 40 is a SiNx layer, and is positioned on and covers the gate electrode 30. The semiconductor layer 50 is an amorphous silicon (a-Si) semiconductor layer, and is positioned on the gate insulating layer 40. The semiconductor layer 50 includes a flat portion 54 and a number of protruding portions 56 perpendicularly protruding from the flat portion 54. Portions of the flat portion 54 between two neighboring protruding portions 56 and the two neighboring protruding portions 56 cooperatively form a channel 52. The shape and the location of the flat portion 54 correspond to the shape and the location of the opaque pattern area 14. The shape and the location of the protruding portions 56 correspond to the shape and the location of the slits 12. In particular, the protruding portions 56 are arranged in a matrix at an equal distance, and are parallel to each other. Each protruding portion 56 is substantially an elongated rectangle, and the width of each protruding portion 56 is in a range from 1.5 micrometers to 2.5 micrometers. The doped semiconductor layer 60 is formed on the protruding portions 56. The data layer 70 is formed on the doped semiconductor layer 60, and corresponds to the protruding portions 56. That is, the data layer 70 has a number of data strips 72. The data strips 72 are arranged in a matrix at an equal distance, and are parallel to each other. Each data strip 72 is substantially an elongated rectangle.

In the thin film transistor 100 and the method for manufacturing the thin film transistor 100 using the photo mask 10, the semiconductor layer 50 is exposed at the channels 52. Thus, the thickness of the semiconductor layer 50 can be easily measured as measuring the thickness of the semiconductor layer 50 is not limited by the channel 52. This can insure the measurement accuracy of the thickness of the semiconductor layer 50. Thus, quality of the thin film transistor 100 is easily controlled.

What is said above are only preferred examples of present invention, not intended to limit the present invention, any modifications, equivalent substitutions and improvements etc. made within the spirit and principle of the present invention, should be included in the protection range of the present invention.

What is claimed is:

1. A photo mask for defining the pattern of a data layer and a semiconductor layer of a thin film transistor, the photo mask having a plurality of slits passing through the photo mask, the slits being parallel to each other and arranged at an equal distance, an opaque pattern area which precludes the slits in the photo mask being defined, and the opaque patter area surrounding the slits.

2. The photo mask of claim 1, wherein each slit is substantially an elongated rectangle.

3. The photo mask of claim 1, wherein the width of each slit is in a range from 1.5 micrometers to 2.5 micrometers.

4. The photo mask of claim 1, wherein the opaque patter area is made of opaque material having transmittance of 0%.

5. A thin film transistor formed by a photo mask of claim 1, comprising:
a substrate;
a gate electrode formed on the substrate;
a gate insulating layer formed on and covering the gate electrode;
a semiconductor layer formed on the gate insulating layer and comprising a flat portion and a plurality of protruding portions protruding from the flat portion, the protruding portions arranged at an equal distance and parallel to each other, the flat portion corresponding to the opaque pattern area, the protruding portions corresponding to the slits;
a doped semiconductor layer formed on the protruding portions; and
a data layer having a plurality of data strips, the data strips arranged at an equal distance and being parallel to each other, each data strip formed on the doped semiconductor layer and corresponding to the protruding portion, and the pattern of the data layer defined by the photo mask.

6. The thin film transistor of claim 5, wherein the substrate is made of glass or plastic.

7. The thin film transistor of claim 5, wherein the gate electrode is a Mo layer, an aluminum layer, a titanium layer, a copper layer, or two layers stacked one on another selected from the Mo layer, the aluminum layer, the titanium layer, and the copper layer.

8. The thin film transistor of claim 5, wherein the gate insulating layer is a SiNx layer.

9. The thin film transistor of claim 5, wherein the semiconductor layer is an amorphous silicon (a-Si) semiconductor layer.

10. The thin film transistor of claim 5, wherein each protruding portion and each data strip are substantially elongated rectangles.

11. The thin film transistor of claim 5, wherein the width of each protruding portion is in a range from 1.5 micrometers to 2.5 micrometers, and the width of each data strip is in a range from 1.5 micrometers to 2.5 micrometers.

12. A method for manufacturing a thin film transistor using the photo mask of claim 1, comprising:
providing a substrate and forming a gate electrode, a gate insulating layer, a semiconductor layer, a doped semiconductor layer, and a data layer on the substrate in an order which is far away from the substrate;
forming an initial photoresist layer on the data layer;
forming an intermediate photoresist layer by means of removing the initial photoresist layer of a certain thickness using a wet-etching process;
providing a photo mask, the photo mask having a plurality of slits passing through the photo mask, the slits being parallel to each other and arranged at an equal distance, an opaque pattern area which precluding the slits in the photo mask being defined, the opaque patter area surrounding the slits;
forming a photoresist layer remain by means of removing portions of the intermediate photoresist layer corresponding to the opaque pattern area using a dry-etching process;
removing portions of the data layer uncovered by the photoresist layer remain via a dry-etching process;
removing portions of the doped semiconductor layer uncovered by the photoresist layer remain and portions of the semiconductor layer uncovered by the photoresist layer remain via a dry-etching process; and
removing the photoresist layer remain.

13. The method of claim 12, wherein the step of forming a photoresist layer remain comprises:
exposing the intermediate photoresist layer by means of striking light on the intermediate photoresist layer though the photo mask; and
developing the intermediate photoresist layer, thereby retaining portions of the intermediate photoresist layer which are stroked by light, and removing portions of the intermediate photoresist layer which are not stroked by light.

14. The method of claim 12, wherein each slit is substantially an elongated rectangle.

15. The method of claim 12, wherein the width of each slit is in a range from 1.5 micrometers to 2.5 micrometers.

16. The method of claim 12, wherein the opaque patter area is made of opaque material having transmittance of 0%.

17. The method of claim 12, wherein the substrate is made of glass or plastic.

18. The method of claim 12, wherein the gate electrode is a Mo layer, an aluminum layer, a titanium layer, a copper layer, or two layers stacked one on another selected from the Mo layer, the aluminum layer, the titanium layer, and the copper layer.

19. The method of claim 12, wherein the gate insulating layer is a SiNx layer.

20. The method of claim 12, wherein the semiconductor layer is an amorphous silicon (a-Si) semiconductor layer.
